(19) United States
(12) Patent Application Publication
(10) Pub. No.: US 2026/0173851 A1
(43) Pub. Date: Jun. 18, 2026

(54) CONTACT PLUGS AND METHODS OF FORMING THE SAME

(71) Applicant: Taiwan Semiconductor Manufacturing Co., Ltd., Hsinchu (TW)

(72) Inventors: Shih-Jung Ho, Hsinchu (TW); Kuan-Kan Hu, Hsinchu (TW); Ku-Feng Yang, Baoshan Township (TW); Szuya Liao, Zhubei (TW); Hao-Chin Huang, Kaohsiung (TW)

(21) Appl. No.: 19/170,151

(22) Filed: Apr. 4, 2025

Related U.S. Application Data
(60) Provisional application No. 63/735,671, filed on Dec. 18, 2024.

(51) Int. Cl. H01L 23/528; H01L 21/768; H10D 62/13; H10D 64/23; H10D 84/01; H10D 84/85

(52) U.S. Cl. CPC H10W 20/435; H10D 62/151; H10D 64/256; H10D 84/017; H10D 84/0186; H10D 84/856; H10W 20/057

(57) ABSTRACT

A method includes forming a conductive feature next to a source/drain region; exposing a first surface of the conductive feature and a first surface of the source/drain region; forming a metal oxide layer on the conductive feature and a silicon oxide layer on the source/drain region; removing the silicon oxide layer, wherein removing the silicon oxide layer exposes a second surface of the source/drain region; forming a silicide region on the second surface of the source/drain region; removing the metal oxide layer, wherein removing the metal oxide layer exposes a second surface of the conductive feature; and depositing a first conductive material on the silicide region and on the second surface of the conductive feature.

### PRIORITY CLAIM AND CROSS-REFERENCE

This application claims the benefit of the following provisionally filed U.S. Patent application: Application No. 63/735,671, filed on Dec. 18, 2024, which application is hereby incorporated herein by reference.

### BACKGROUND

Semiconductor devices are used in a variety of electronic applications such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. As the minimum feature sizes are reduced, however, additional problems arise and should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A, 1B, 2, 3, 4, 5, 6, 7, 8, and 9 are views of intermediate stages in the formation of a contact plug of a stacking transistor structure, in accordance with some embodiments.

FIGS. 10, 11, 12, 13, 14, 15, and 16 are views of intermediate stages in the formation of a contact plug of a stacking transistor structure, in accordance with some embodiments.

FIGS. 17, 18, 19, 20, 21, 22, and 23 are views of intermediate stages in the formation of a contact plug of a stacking transistor structure, in accordance with some embodiments.

FIGS. 24, 25, 26, and 27 are views of intermediate stages in the formation of a contact plug of a stacking transistor structure, in accordance with some embodiments.

FIGS. 28, 29, 30, 31, and 32 are views of intermediate stages in the formation of a contact plug of a stacking transistor structure, in accordance with some embodiments.

FIGS. 33, 34, 35, 36, and 37 are views of intermediate stages in the formation of a contact plug of a stacking transistor structure, in accordance with some embodiments.

FIGS. 38, 39, and 40 are views of intermediate stages in the formation of a contact plug of a stacking transistor structure, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various representative embodiments are described with respect to contact plugs within stacking transistor structures. Complementary Field-Effect Transistors (CFETs), silicide regions, contact plugs, and the method of forming the same are provided. In accordance with some embodiments of the present disclosure, an interface between two contact plugs is formed with little or no silicide residue or nitride residue. Reducing or eliminating the residue between the contact plugs allows for reduced resistance and improved electrical connection. Additionally, the interface between the contact plugs is formed largely free of metal oxide, which can also reduce resistance and improve electrical connection.

It is appreciated that while the discussion herein in presented in the context of the formation of stacking transistors including Gate-All-Around (GAA) transistors (such as nanostructure-FETs), the concept of the present disclosure can also be applied to the formation of other types of transistors such as planar transistors, Fin Field-Effect Transistors (FinFETs), and the like. Throughout the description, the terms “FET” and “transistor” are used interchangeably.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

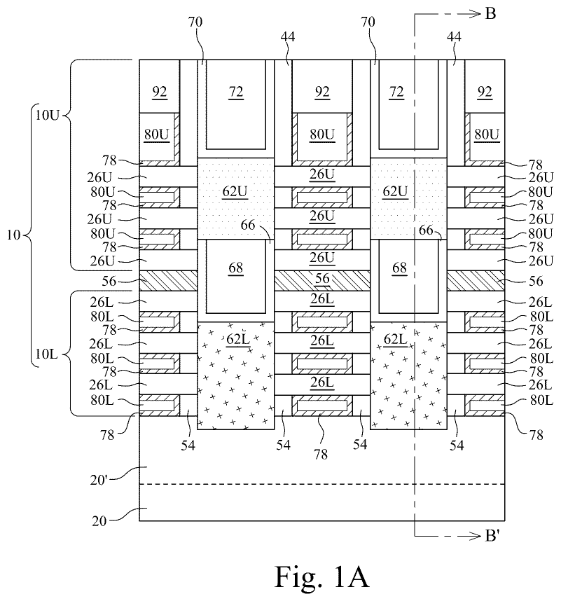

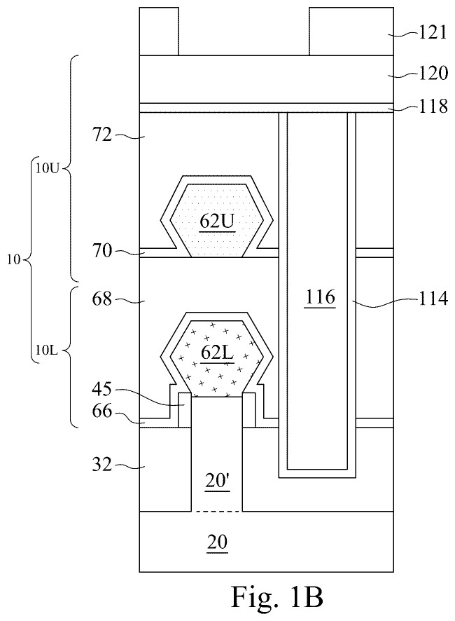

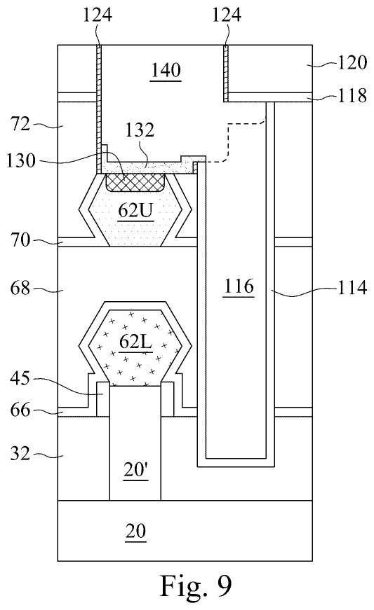

FIGS. 1A-1B through 9 illustrate cross-sectional views of intermediate stages in the formation of a stacking transistor structure, in accordance with some embodiments. In particular, FIGS. 1B through 9 illustrate intermediate stages in the formation of a contact plug 140 (see FIG. 9) of a stacking transistor structure, in accordance with some embodiments. The stacking transistor structure may be a Complementary Field-Effect Transistor (CFET) structure, in some cases. FIGS. 1A-1B illustrate an example stacking transistor 10, in accordance with some embodiments. The stacking transistor 10 includes multiple vertically stacked FETs. For example, a stacking transistor may include a lower nanostructure-FET 10L of a first device type (e.g., n-type/p-type) and an upper nanostructure-FET 10U of a second device type (e.g., p-type/n-type). When the stacking transistor is a CFET, the second device type of the upper nanostructure-FET 10U is opposite to the first device type of the lower nanostructure-FET 10L. The nanostructure-FETs 10U and 10L include semiconductor nanostructures 26 (including lower semiconductor nanostructures 26L and upper semiconductor nanostructures 26U), where the semiconductor nanostructures 26 act as the channel regions for the nanostructure-FETs. The lower semiconductor nanostructures 26L are for the lower nanostructure-FET 10L, and the upper semiconductor nanostructures 26U are for the upper nanostructure-FET 10U. In other embodiments, the stacking transistors may be applied to other types of transistors (e.g., FinFETs, or the like) as well.

In some embodiments, the stacking transistor 10 is formed on a wafer, which may include a substrate 20. The substrate 20 may be a semiconductor substrate, such as a bulk semiconductor, a semiconductor-on-insulator (SOI) substrate, or the like, which may be doped (e.g., with a p-type or an n-type dopant) or undoped. A SOI substrate may include a layer of a semiconductor material formed on an insulator layer. The insulator layer may be, for example, a buried oxide (BOX) layer, a silicon oxide layer, or the like. The insulator layer is provided on a substrate, such as a silicon or glass substrate. Other substrates, such as a multilayered or gradient substrate may also be used. In some embodiments, the semiconductor material of the substrate 20 may include silicon, germanium, carbon-doped silicon, a III-V compound semiconductor, or the like, or combinations thereof.

Gate dielectrics 78 encircle the respective semiconductor nanostructures 26. Gate electrodes 80 (including a lower gate electrode 80L and an upper gate electrode 80U) are over the gate dielectrics 78. The gate dielectrics 78 and gate electrodes 80 form “gate stacks” or “gate structures” between the semiconductor nanostructures 26. Upper gate stacks include gate dielectrics 78 and upper gate electrodes 80U. Lower gate stacks include gate dielectrics 78 and lower gate electrodes 80L.

Dielectric isolation layers 56 are formed to isolate the gate stacks of the upper FETs 10U from the gate stacks of the lower FETs 10L. The semiconductor layers adjacently above and below the dielectric isolation layers 56 may be dummy semiconductor layers (e.g., dummy nanostructures), in some embodiments.

Source/drain regions 62 (including lower source/drain regions 62L and upper source/drain regions 62U) are disposed on opposing sides of the gate stacks (e.g., the gate dielectrics 78 and the respective gate electrodes 80). A source/drain region 62 may refer to a source or a drain, individually or collectively dependent upon the context. Isolation features (not shown) may be formed to separate desired ones of the source/drain regions 62 and/or desired ones of the gate electrodes 80.

Inner spacers 54, which are dielectric spacers, are formed on the opposing sides of the portions of gate stacks, which portions are between semiconductor layers 26. Inner spacers 54 electrically insulate the source/drain regions 62L and 62U from the corresponding parts of gate stacks to prevent and reduce leakage. Gate spacers 44 are formed over the multilayer stacks and on the sidewalls of gate stacks 90. The gate spacers 44 may be formed by conformally forming one or more dielectric layers and subsequently etching the dielectric layers anisotropically. The applicable dielectric materials may include silicon oxide, silicon nitride, silicon oxynitride, silicon oxycarbonitride, or the like, which may be formed by a deposition process such as Chemical Vapor Deposition (CVD), Atomic Layer Deposition (ALD), or the like.

The source/drain regions 62L and 62U are formed laterally between the multilayer stacks that comprise the channel regions (e.g., the semiconductor nanostructures 26) and the gate stacks (e.g., the gate dielectrics 78 and the gate electrodes 80). Lower source/drain regions 62L are formed over and contacting a substrate, which includes substrate 20. The lower source/drain regions 62L are further in contact with the lower semiconductor nanostructures 26L and are not in contact with the upper semiconductor nanostructures 26U.

The lower source/drain regions 62L are epitaxially grown, and have a conductivity type that is suitable for the device type (p-type or n-type) of the lower nanostructure-FETs. When lower source/drain regions 62L are n-type source/drain regions, the respective material may include silicon or carbon-doped silicon, which is doped with an n-type dopant such as phosphorous, arsenic, or the like. When lower source/drain regions 62L are p-type source/drain regions, the respective material may include silicon or silicon germanium, which is doped with a p-type dopant such as boron, indium, or the like. The lower source/drain regions 62L may be in-situ doped, and may be, or may not be, implanted with the corresponding p-type or n-type dopants

A first contact etch stop layer (CESL) 66 and a first inter-layer dielectric (ILD) 68 are formed over the lower source/drain regions 62L. The applicable dielectric material of the first ILD 68 may include phospho-silicate glass (PSG), boro-silicate glass (BSG), boron-doped phospho-silicate glass (BPSG), undoped silicate glass (USG), silicon oxide, or the like. The first CESL 66 may be formed of a dielectric material having a high etching selectivity from the etching of the first ILD 68. For example, the first CESL 66 may comprise silicon nitride, silicon oxide, silicon oxynitride, or the like, which may be formed by any suitable deposition process, such as CVD, ALD, or the like.

Upper source/drain regions 62U are formed overlapping the first CESL 66 and the first ILD 68, and overlapping the lower source/drain regions 62L. The materials of upper source/drain regions 62U may be selected from the same candidate group of materials for forming lower source/drain regions 62L, depending on the desired conductivity type of upper source/drain regions 62U. The conductivity type of the upper source/drain regions 62U may be opposite the conductivity type of the lower source/drain regions 62L. Alternatively stated, the upper source/drain regions 62U may be oppositely doped than the lower source/drain regions 62L. The upper source/drain regions 62U may be in-situ doped, and/or may be implanted, with an n-type or p-type dopant.

A second CESL 70 and a second ILD 72 are formed over the upper source/drain regions 62U. The materials may be similar to, and may be the same as or different from, the materials and the formation methods of the first CESL 66 and first ILD 68, respectively, and are not discussed in detail herein.

FIG. 1B illustrates a cross-sectional view of the structure as shown in FIG. 1A. The illustrated cross-section may be similar to the cross-section B-B′ indicated in FIG. 1A. Dielectric isolation regions 32, also sometimes referred to as Shallow Trench Isolation (STI) regions 32, are formed over the substrate 20. Semiconductor strips 20′ (also refer to FIG. 1A) are formed between the STI regions 32. The semiconductor strips 20′ may be considered semiconductor fins, in some cases. Fin spacers 45 may be formed on the sidewalls of the top portions of the semiconductor strips 20′. The lower source/drain regions 62L, the first CESL 66, the first ILD 68, the upper source/drain regions 62U, the second CESL 70, and the second ILD 72 are also illustrated in FIG. 1B.

FIG. 1B further illustrates the formation of a contact plug 116. In some cases, the contact plug 116 may be considered a vertical local interconnect (VLI), a via, an interconnect structure, or the like. In accordance with some embodiments, the formation of the contact plug 116 includes etching the second ILD 72, the second CESL 70, the first ILD 68, and the first CESL 66, so that a trench is formed. The trench may extend to an intermediate level between the top surface and the bottom surface of isolation region 32. A dielectric liner 114 is formed in the trench. In accordance with some embodiments, the formation of the dielectric liner 114 includes a conformal deposition process such as Chemical Vapor Deposition (CVD), Atomic Layer Deposition (ALD), Physical Vapor Deposition (PVD), or the like. In accordance with some embodiments, the material of dielectric liner 114 may include silicon nitride, a metal oxide or a metal nitride of a metal such as hafnium, titanium, aluminum, tungsten, niobium, rhenium, the like, or combinations thereof. For example, in some embodiments, the dielectric liner 114 comprises titanium nitride or tantalum nitride, though other materials are possible.

Conductive material of the contact plug 116 is then deposited on the dielectric liner 114. In accordance with some embodiments, the conductive material of the contact plug 116 comprises a metal such as tungsten, cobalt, copper, nickel, molybdenum, ruthenium, iridium, the like, alloys thereof, or combinations thereof. In accordance with some embodiments, the contact plug 116 has a single-layer structure, with the entire contact plug 116 being formed of a homogeneous material.

After the deposition of the materials for forming the contact plug 116, a planarization process such as a chemical mechanical polishing (CMP) process or a mechanical grinding process is performed to remove excess material, with the remaining material forming the contact plug 116. The top surfaces of the contact plug 116 and the dielectric liner 114 are coplanar, and in some embodiments may further be coplanar with a top surface of the second ILD 72. In this manner, the contact plug 116 is encircled by the dielectric liner 114.

As shown in FIG. 1B, an etch stop layer (ESL) 118 is formed. The etch stop layer 118 may comprise aluminum nitride, aluminum oxide, silicon oxycarbide, the like, or multilayers thereof. A dielectric layer 120 is deposited over the etch stop layer 118. The dielectric layer 120 may comprise silicon oxide, silicon nitride, silicon oxynitride, silicon carbide, or the like. In some embodiments, a patterned etching mask 121, which may comprise a photoresist, hard mask, or the like, is formed over the dielectric layer 120.

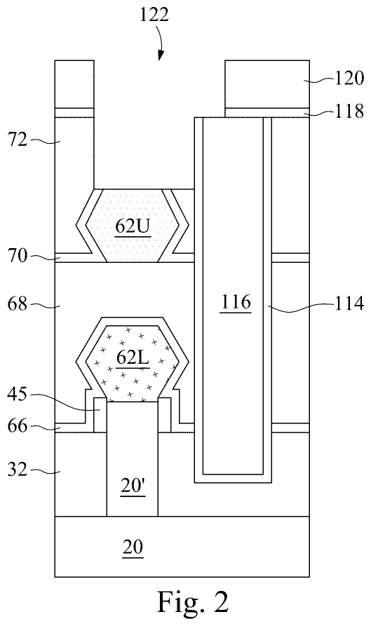

In FIG. 2, the etch stop layer 118 and the dielectric layer 120 are patterned to form an opening 122, in accordance with some embodiments. The opening 122 exposes the dielectric liner 114 and the contact plug 116. The opening 122 also extends into the second ILD 72 and through the second CESL 70 to expose the upper source/drain region 62U. The opening 122 may be formed using one or more etching processes, which may use the patterned etching mask 121 as an etching mask. The opening exposes a top surface of the upper source/drain region 62U. After exposing the upper source/drain region 62U and the contact plug 116, the patterned etching mask 121 may be removed using a suitable process, such as an ashing or etching process.

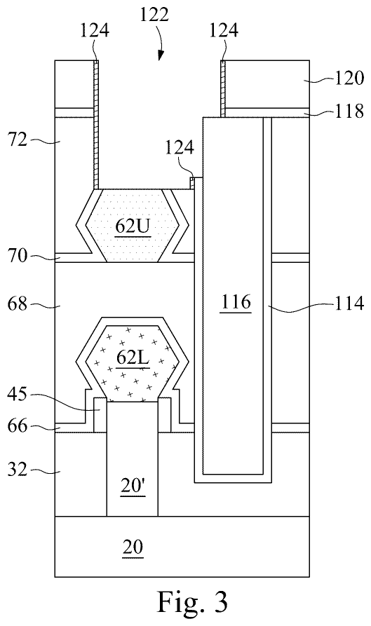

In FIG. 3, dielectric liners 124 are formed on some sidewall surfaces of the opening 122, in accordance with some embodiments. In some embodiments, the dielectric liners 124 are deposited as a conformal layer using a suitable conformal deposition process. For example, the dielectric liners 124 may be deposited using ALD, CVD, PVD, or the like. An anisotropic etching process is then performed to remove portions of the conformal layer on horizontal surfaces, leaving the remaining vertical portions as the dielectric liners 124. During the anisotropic etching process, the exposed portions of dielectric liner 114 may also be recessed. For example, a portion of the dielectric liner 114 may be removed to expose a sidewall of the contact plug 116, as shown in FIG. 3. The material of the dielectric liners 124 may be selected from the same group of candidate materials for forming dielectric liner 114, and may be the same as or different from the material of dielectric liner 114. For example, dielectric liners 124 may be formed of and/or comprise silicon nitride. Other materials or formation techniques are possible.

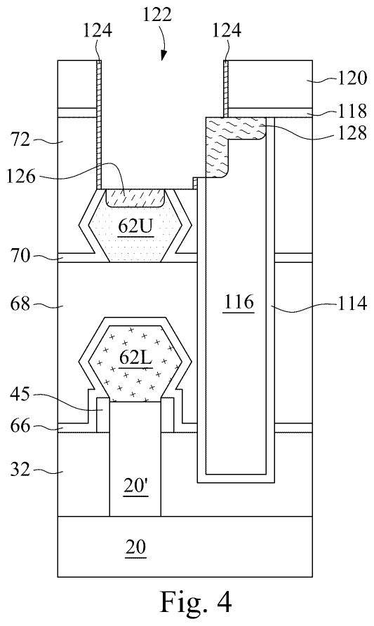

Referring to FIG. 4, oxide layers may be formed on the upper source/drain region 62U and on the contact plug 116, in some cases. The oxide layers may be formed, for example, due to a vacuum break during transfer of the structure between process steps. For example, a silicon oxide layer 126 may be formed on the upper source/drain region 62U due to oxidation of exposed surfaces of the upper source/drain region 62U, and a metal oxide layer 128 may be formed on the contact plug 116 due to oxidation of exposed surfaces of the contact plug 116. The metal oxide layer 128 thus comprises an oxide of the metal in contact plug 116. For example, when contact plug 116 comprises tungsten, the metal oxide layer 128 comprises tungsten oxide (e.g., WOₓ). The shape and size of the metal oxide layer 128 may be different than shown in FIG. 4.

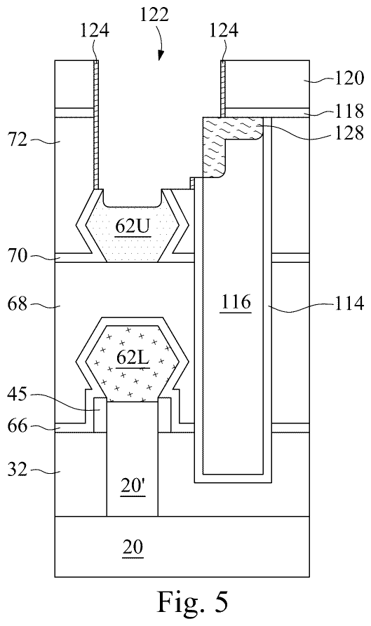

In FIG. 5, a first pre-clean process is performed to remove the silicon oxide layer 126, in accordance with some embodiments. The first pre-clean process may comprise, for example, a mixture of HF and NH₃ process gases, though other processes are possible. After performing the first pre-clean process, the silicon oxide layer 126 is removed, and the underlying upper source/drain region 62U is exposed. In some embodiments, the first pre-clean process does not remove the metal oxide layer 128, as shown in FIG. 5.

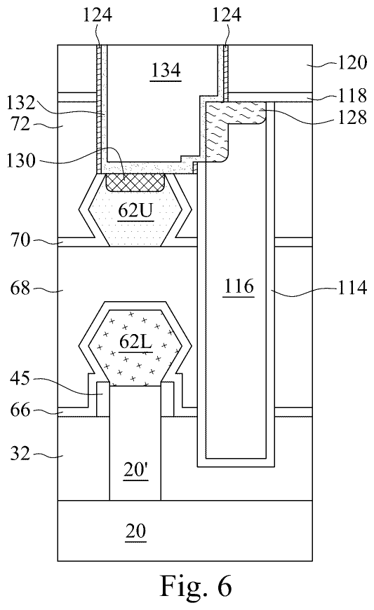

In FIG. 6, a silicide region 130 is formed on the upper source/drain region 62U, in accordance with some embodiments. In some embodiments, the silicide region 130 may be formed by exposing the structure to a metal-containing precursor. The metal-containing precursor reacts with surfaces of the upper source/drain region 62 to form the silicide region 130 and may deposit on other surfaces to form a residue layer 132 (also referred to as residue 132), described in greater detail below. The metal of the silicide region 130 may comprise titanium, vanadium, zinc, niobium, aluminum, or other suitable metals. In some embodiments, a nitride layer (not separately illustrated) is formed over the silicide region 130 to reduce oxidation. The nitride layer may be deposited as a separate layer onto the silicide region 130, or a nitridation process (e.g., a nitriding process or a nitrogen treatment process) may be performed on the silicide region 130 to form a nitride layer at or near top surfaces of the silicide region 130. For example, for embodiments in which the silicide region 130 is a titanium silicide (e.g., TiSiₓ), the nitride layer may comprise titanium nitride (e.g., TiN) and/or titanium silicide nitride (e.g., TiSiN). Other materials are possible. In some cases, an electrical conductivity of the silicide region 130 is greater than an electrical conductivity of the upper source/drain region 62U.

In some cases, forming the silicide region 130 also forms a residue layer 132 within the opening 122. The residue layer 132 may extend on surfaces of the silicide region 130, the dielectric liners 124, the metal oxide layer 128, and/or the contact plug 116, for example. The residue layer 132 may comprise similar material(s) as the metal-containing precursor, the silicide region 130, and/or the nitride layer. For example, for embodiments in which the silicide region 130 is titanium silicide, the residue layer 132 may comprise titanium and/or titanium nitride. Other materials are possible.

Further in FIG. 6, a metal fill 134 is deposited to fill the opening 122, in accordance with some embodiments. The metal fill 134 is deposited on the residue layer 132, and thus is deposited over the silicide region 130 and over the contact plug 116. In some embodiments, the metal fill 134 is the same metal as the contact plug 116. In other embodiments, the metal fill 134 and the contact plug 116 are different conductive materials. For example, the metal fill 134 may be a metal such as tungsten, molybdenum, ruthenium, iridium, or the like. The metal fill 134 may be deposited using a suitable technique, which may be similar to that used to deposit the material of the contact plug 116. In some cases, the contact plug 116 and the metal fill 134 are separated by the residue layer 132. In some cases, the metal fill 134 may be considered a “sacrificial metal” that is at least partially removed in subsequent process steps, described below.

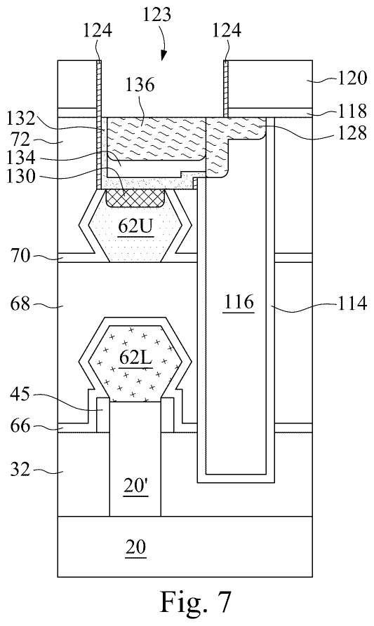

In FIG. 7, an etching process is performed to recess the metal fill 134, in accordance with some embodiments. The etching process removes upper portions of the metal fill 134, and may also remove upper portions of the residue layer 132. The etching process may be considered a “pull-back etch” or the like, and may include any suitable etching process. In some cases, the etching process may oxidize portions of the metal fill 134, such that after the etching process, a metal oxide layer 136 is present at or near a top surface of the remaining metal fill 134. The metal oxide layer 136 may comprise an oxide of the metal of the metal fill 134. For example, when the metal fill 134 comprises tungsten, the metal oxide layer 136 comprises tungsten oxide. Thus, for embodiments in which the metal fill 134 and the contact plug 116 are the same metal, the metal oxide layer 136 and the metal oxide layer 128 may be similar metal oxides. The shape and size of the metal oxide layer 136 may be different than shown in FIG. 4. For example, in some embodiments, portions of the metal fill 134 underneath the metal oxide layer 136 are not oxidized, as shown in FIG. 7. In other embodiments, all of the remaining metal fill 134 has been oxidized by the etching process (e.g., only the metal oxide layer 136 remains). After performing the etching process, a top surface of the remaining metal fill 134 and/or metal oxide layer 136 may be higher than, lower than, or about the same as a top surface of the contact plug 116 and/or the metal oxide layer 128. As shown in FIG. 7, the metal oxide layer 136 and the metal oxide layer 128 may be separated by the residue layer 132. Recessing the metal fill 134 forms an opening 123, which may partially overlap the previously-formed opening 122.

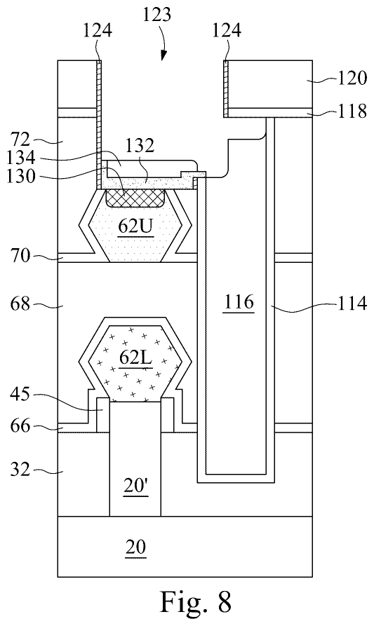

In FIG. 8, a second pre-clean process is performed to remove the metal oxide layer 128 and the metal oxide layer 136, in accordance with some embodiments. The second pre-clean process is a different process than the first pre-clean process. The second pre-clean process may also remove portions of the residue layer 132 adjacent to the metal oxide layer 128 and/or the metal oxide layer 136. After performing the second pre-clean process, at least a portion of the metal oxide layer 128 is removed, and the contact plug 116 is exposed. In some embodiments, a portion of the metal fill 134 remains after removing the metal oxide layer 136, as shown in FIG. 8. In other embodiments, the metal fill 134 is fully removed after the second pre-clean process. A portion of the residue layer 132 may remain over the silicide region 130, in some cases. In some embodiments, the second pre-clean process may remove both the metal oxide layer 128 and the metal oxide layer 136 whether or not the metal oxide layer 128 and the metal oxide layer 136 are similar metal oxides.

In FIG. 9, a metal fill is deposited into the opening 123 to form a contact plug 140, in accordance with some embodiments. The contact plug 140 is electrically connected to the upper source/drain region 62U by the silicide region 130 and the residue layer 132 (if present), and thus the contact plug 140 may also be referred to as an upper source/drain contact plug. The metal fill physically contacts the exposed surfaces of the contact plug 116, and thus the contact plug 140 is physically and electrically connected to the contact plug 116. The metal fill may be a material similar to those of the metal fill 134 and/or the contact plug 116. For example, in accordance with some embodiments, the metal fill is a conductive material such as tungsten, molybdenum, ruthenium, iridium, the like, or alloys thereof. The metal fill may fully fill the opening 123, in some embodiments. After the deposition of the metal fill for forming contact plug 140, a planarization process such as a CMP process or a mechanical grinding process is performed to remove excess portions of the metal fill, with the remaining portions of the metal fill forming the contact plug 140. After performing the planarization process, top surfaces of the contact plug 140, dielectric liners 124, and the dielectric layer 120 may be level or coplanar. The contact plug 140 is at least partially encircled by dielectric liners 124. In some cases, an electrical conductivity of the silicide region 130 is less than an electrical conductivity of the contact plug 140 and/or the contact plug 116. In some cases, an electrical conductivity of the silicide region 130 is between an electrical conductivity of the upper source/drain region 62U and an electrical conductivity of the contact plug 140.

In some cases, the residue layer 132 may be relatively resistive (e.g., more resistive than the contact plug 116 and/or the contact plug 140). Thus, removing the residue layer 132 from the contact plug 116 as described herein can allow for reduced resistance between the contact plug 140 and the contact plug 116, which can improve device performance. For example, in some cases, it may be difficult to remove portions of residue without damaging or removing the silicide region. The techniques described herein allow for partial removal of residue without risk of damage to the silicide region. Additionally, removing the metal oxide layer 128 from the contact plug 116 can also reduce resistance, improve the electrical connection between the contact plug 116 and the contact plug 140, and improve electrical performance of the device. In this manner, the electrical connection between conductive features, such as a source/drain contact plug and a VLI, may be improved.

Additional processing may be performed on the structure. For example, additional conductive features (not separately illustrated) such as redistribution lines, vias, or contact plugs may be formed on the front side or on the back side of the structure. The back side conductive features may include contact plugs that are electrically connected to the lower source/drain region 62L and/or to the contact plug 116. These back side contact plugs may be formed using techniques similar to those described for FIGS. 1A-9 or similar to those described elsewhere in the present disclosure. For example, a “front side” contact plug 140 may be connected to an upper source/drain region 62U and a contact plug 116, and a “back side” contact plug may be connected to a lower source/drain region 62L and may also be connected to the same contact plug 116. In such a case, the back side contact plug may be formed using techniques similar to those described herein for forming the contact plug 140 or other embodiment contact plugs. Other conductive features or other additional processing steps are possible.

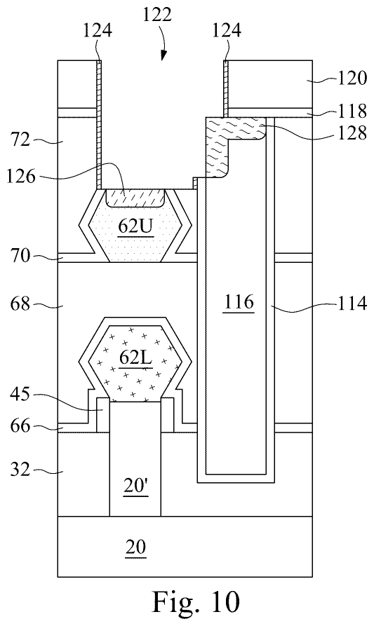

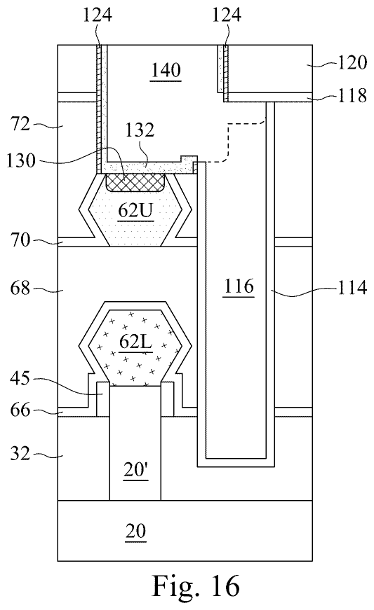

FIGS. 10 through 16 illustrate intermediate stages in the formation of a contact plug 140 (see FIG. 16) of a stacking transistor structure, in accordance with some embodiments. The contact plug 140 is similar to that described for FIG. 9, except that a self-assembled material (SAM) is utilized during formation of the contact plug 140 to provide an improved connection between the contact plug 140 and the contact plug 116. Some of the materials and techniques used in FIGS. 10-15 are similar to those described previously for FIGS. 1A-9, and accordingly some details may not be repeated. FIG. 10 illustrates a structure similar to that shown previously in FIG. 4, which may be formed using materials and techniques similar to those described for FIGS. 1A-4. For example, FIG. 10 illustrates the structure after oxidation has occurred on the upper source/drain region 62U and on the contact plug 116, forming a silicon oxide layer 126 and a metal oxide layer 128, respectively.

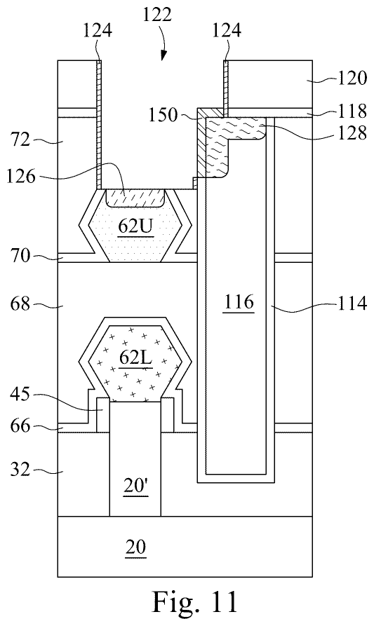

In FIG. 11, a self-assembled material (SAM) 150 is selectively formed on the metal oxide layer 128, in accordance with some embodiments. The SAM 150 may be a material that selectively forms on metal-containing surfaces, and thus the SAM 150 may deposit on surfaces the metal oxide layer 128 and/or the contact plug 116. Little or no SAM 150 deposits on the dielectric liners 124, the silicon oxide layer 126, or the upper source/drain region 62U. The SAM 150 may fully or partially cover the exposed surfaces of the metal oxide layer 128 and/or the contact plug 116.

The SAM 150 may comprise a suitable self-assembling material, which may form as a monolayer in some cases. The SAM 150 may be deposited using a suitable technique, such as exposing surfaces to a SAM precursor. For example, in some embodiments, the SAM precursor may be a thiol with an R-group comprising a 3-carbon chain to a 20-carbon chain, such as 16-mercaptohexadecanoic acid, 11-mercaptoundecanoic acid, lipoic acid, or the like; a phosphonic acid with an R-group comprising a 3-carbon chain to a 20-carbon chain, such as NDPA, HDPA, PUA, PHA, or the like; a carboxylic acid with an R-group comprising a 3-carbon chain to a 20-carbon chain, such as stearic acid, oleic acid, dodecanoic acid, or the like; or a silane with an R-group comprising a 3-carbon chain to a 20-carbon chain, such as dodecyltrichlorosilane, n-octadecyltrichlorosilane, (tridecafluoro-1,1,2,2-tetrahydrooctyl)trichlorosilane, docosenyltriethoxysilane, or the like. These are examples, and other SAM precursors or SAM materials may be used to form the SAM 150.

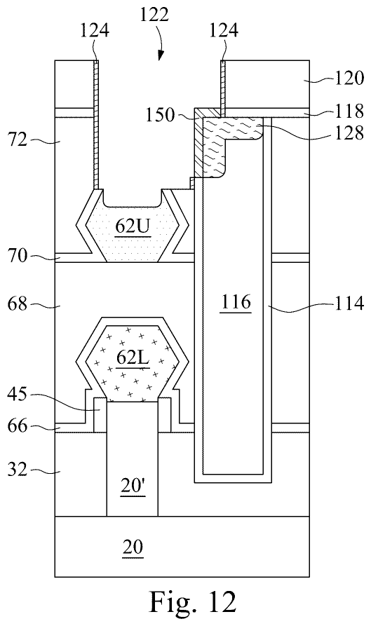

In FIG. 12, a pre-clean process is performed to remove the silicon oxide layer 126, in accordance with some embodiments. The pre-clean process may be similar to the first pre-clean described previously for FIG. 5. After performing the pre-clean process, the silicon oxide layer 126 is removed, and the underlying upper source/drain region 62U is exposed. In some embodiments, the pre-clean process does not remove the SAM 150 or the underlying metal oxide layer 128.

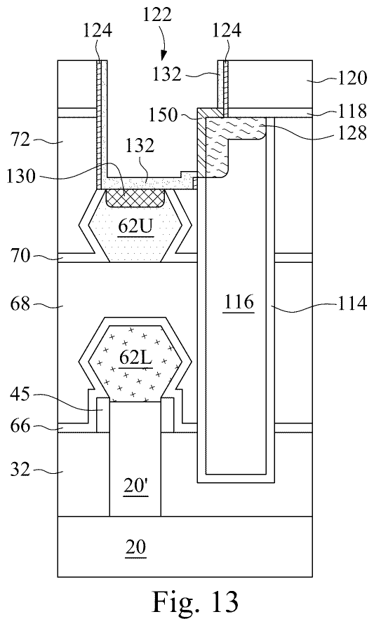

In FIG. 13, a silicide region 130 is formed on the upper source/drain region 62U, in accordance with some embodiments. The silicide region 130 may be formed using materials or techniques similar to those described previously for FIG. 6. For example, in some embodiments, the silicide region 130 may be formed by exposing the structure to a metal-containing precursor that reacts with surfaces of the upper source/drain region 62 to form the silicide region 130. A nitride layer may be formed on the silicide region 130, in some cases. For example, for embodiments in which the silicide region 130 is a titanium silicide (e.g., TiSiₓ), the nitride layer may comprise titanium nitride (e.g., TiN) and/or titanium silicide nitride (e.g., TiSiN). Other materials are possible.

In some cases, a residue layer 132 may be formed within the opening 122, which may be similar to the reside layer 132 described previously for FIG. 6. In some embodiments, the residue 132 forms at a lower rate on the SAM 150 than on other surfaces of the structure. In this manner, little or no residue 132 may be formed on the SAM 150, and little or no residue 132 may be formed on the metal oxide layer 128. Due to the presence of the SAM 150, the metal oxide layer 128 may be free of the residue layer 132, in some embodiments. In some cases, residue 132 may be deposited on some portions of the metal oxide layer 128, such as on portions that are incompletely or insufficiently covered by the SAM 150.

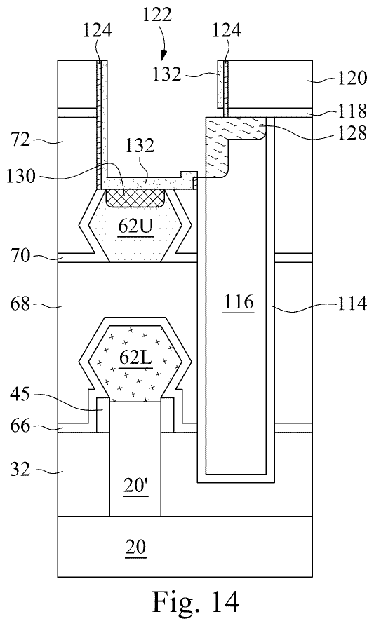

In FIG. 14, the SAM 150 is removed, in accordance with some embodiments. The SAM 150 may be removed using a suitable process, such as an etching process, an ashing process, a chemical rinse, or another process. After removing the SAM 150, surfaces of the metal oxide layer 128 and/or the contact plug 116 are exposed. After removing the SAM 150, the metal oxide layer 128 may be free of the residue layer 132, in some embodiments. In some cases, residue 132 may remain on surfaces of the metal oxide layer 128 after removing the SAM 150.

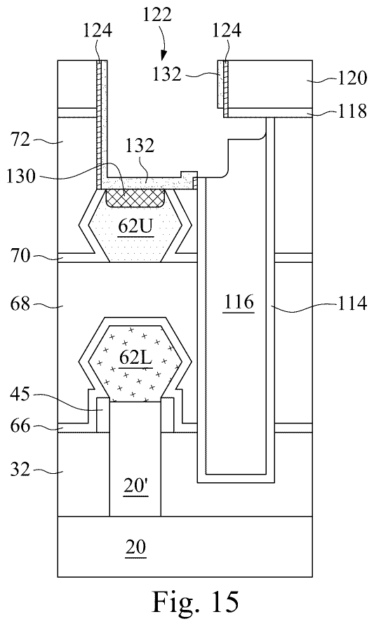

In FIG. 15, a pre-clean process is performed to remove the metal oxide layer 128, in accordance with some embodiments. The pre-clean process may be similar to the second pre-clean process previously described for FIG. 8. After performing the pre-clean process, at least a portion of the metal oxide layer 128 is removed, and the contact plug 116 is exposed. A portion of the residue layer 132 may remain over the silicide region 130, in some cases.

In FIG. 16, a metal fill is deposited into the opening 122 to form a contact plug 140, in accordance with some embodiments. The metal fill and the contact plug 140 may be similar to those previously described for FIG. 9. For example, the contact plug 140 is electrically connected to the upper source/drain region 62U and is physically and electrically connected to the contact plug 116. The metal fill may fully fill the opening 122, in some embodiments. The metal fill may be a material similar to those of the metal fill 134 and/or the contact plug 116. In this manner, the interface between the contact plug 140 and the contact plug 116 may be free of residue 132, which can reduce resistance and improve device performance.

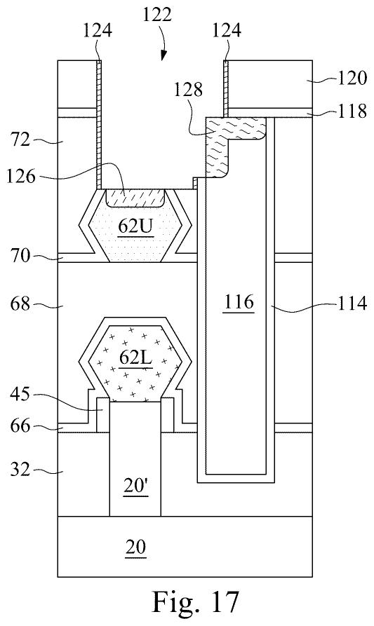

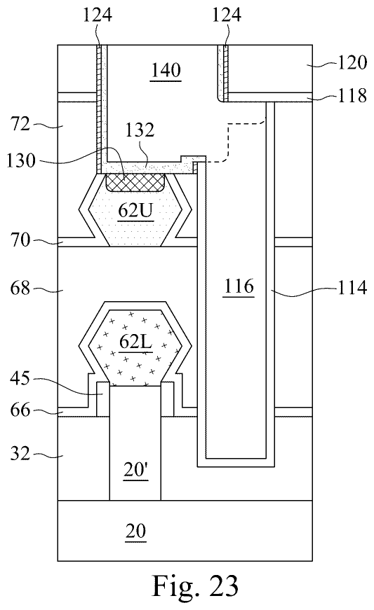

FIGS. 17 through 23 illustrate intermediate stages in the formation of a contact plug 140 (see FIG. 23) of a stacking transistor structure, in accordance with some embodiments. The process of FIGS. 17-23 is similar to the process of FIGS. 10-16, except that the SAM 150 is deposited after removing the metal oxide layer 128 rather than before removing the metal oxide layer 128. Some of the materials and techniques used in FIGS. 17-23 are similar to those described previously for FIGS. 1A-16, and accordingly some details may not be repeated. FIG. 17 illustrates a structure similar to that shown previously in FIG. 4 and FIG. 10, which may be formed using materials and techniques similar to those described for FIGS. 1A-4. For example, FIG. 17 illustrates the structure after oxidation has occurred on the upper source/drain region 62U and on the contact plug 116, forming a silicon oxide layer 126 and a metal oxide layer 128, respectively.

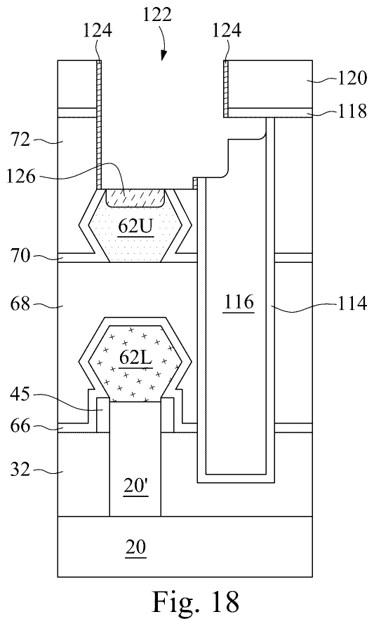

In FIG. 18, a pre-clean process is performed to remove the metal oxide layer 128, in accordance with some embodiments. The pre-clean process may be similar to the second pre-clean previously described for FIG. 8. After performing the pre-clean process, at least a portion of the metal oxide layer 128 is removed, and the contact plug 116 is exposed. In some embodiments, the pre-clean process does not remove the silicon oxide layer 126, such that the silicon oxide layer 126 remains on the upper source/drain region 62U after the pre-clean process has been performed.

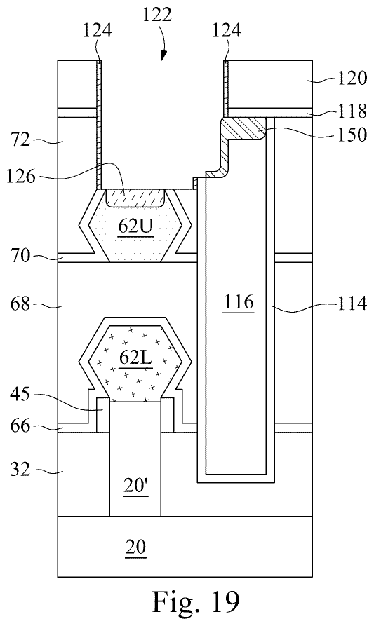

In FIG. 19, a SAM 150 is selectively formed on the contact plug 116, in accordance with some embodiments. The SAM 150 may be a material similar to that described previously for FIG. 11, and may be formed using similar techniques or precursors. For example, the SAM 150 may be a material that selectively forms on metal-containing surfaces, and thus the SAM 150 deposits on surfaces of the contact plug 116 exposed by the previous pre-clean process. Little or no SAM 150 deposits on the dielectric liners 124, the silicon oxide layer 126, or the upper source/drain region 62U. The SAM 150 may fully or partially cover the exposed surfaces of the contact plug 116.

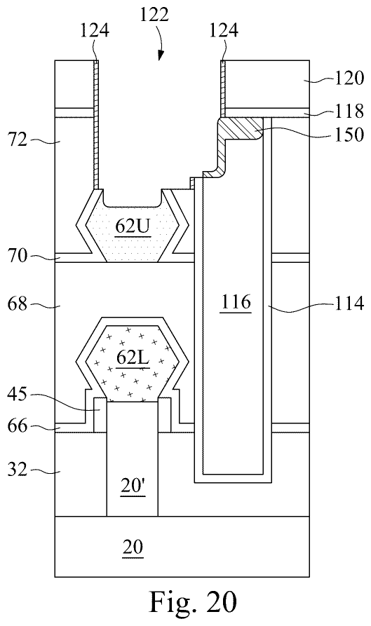

In FIG. 20, a pre-clean process is performed to remove the silicon oxide layer 126, in accordance with some embodiments. The pre-clean process may be similar to the first pre-clean described previously for FIG. 5. After performing the pre-clean process, the silicon oxide layer 126 is removed, and the underlying upper source/drain region 62U is exposed. In some embodiments, the pre-clean process does not remove the SAM 150.

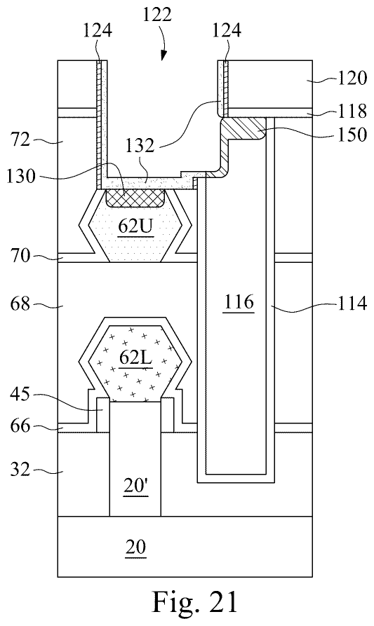

In FIG. 21, a silicide region 130 is formed on the upper source/drain region 62U, in accordance with some embodiments. The silicide region 130 may be formed using materials or techniques similar to those described previously for FIG. 6. For example, in some embodiments, the silicide region 130 may be formed by exposing the structure to a metal-containing precursor that reacts with surfaces of the upper source/drain region 62 to form the silicide region 130. A nitridation process may be performed, in some cases. For example, for embodiments in which the silicide region 130 is a titanium silicide (e.g., TiSiₓ), the nitride layer may comprise titanium nitride (e.g., TiN) and/or titanium silicide nitride (e.g., TiSiN). Other materials are possible.

In some cases, a residue layer 132 may be formed within the opening 122, which may be similar to the reside layer 132 described previously for FIG. 6. In some embodiments, the residue 132 forms at a lower rate on the SAM 150 than on other surfaces of the structure. In this manner, little or no residue 132 may be formed on the SAM 150, and little or no residue 132 may be formed on the contact plug 116. Due to the presence of the SAM 150, the contact plug 116 may be free of the residue layer 132, in some embodiments. In some cases, residue 132 may be deposited on some portions of the contact plug 116, such as on portions that are incompletely or insufficiently covered by the SAM 150.

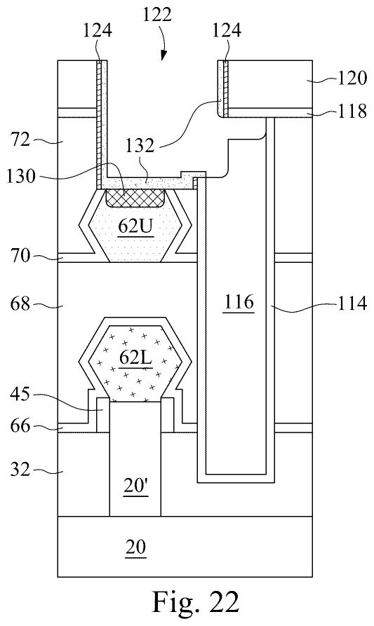

In FIG. 22, the SAM 150 is removed, in accordance with some embodiments. The SAM 150 may be removed using techniques similar to those described previously for FIG. 14. After removing the SAM 150, surfaces of the contact plug 116 are exposed. After removing the SAM 150, the contact plug 116 may be free of the residue layer 132, in some embodiments. In some cases, residue 132 may remain on surfaces of the contact plug 116 after removing the SAM 150.

In FIG. 23, a metal fill is deposited into the opening 122 to form a contact plug 140, in accordance with some embodiments. The metal fill and the contact plug 140 may be similar to those previously described for FIG. 9. For example, the contact plug 140 is electrically connected to the upper source/drain region 62U and is physically and electrically connected to the contact plug 116. The metal fill may fully fill the opening 122, in some embodiments. The metal fill may be a material similar to those of the metal fill 134 and/or the contact plug 116. In this manner, the interface between the contact plug 140 and the contact plug 116 may be free of residue 132, which can reduce resistance and improve device performance.

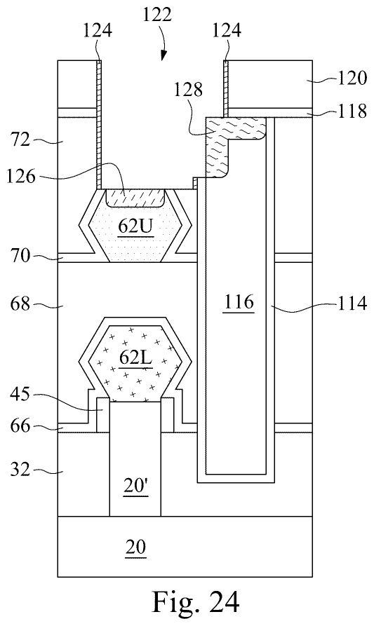

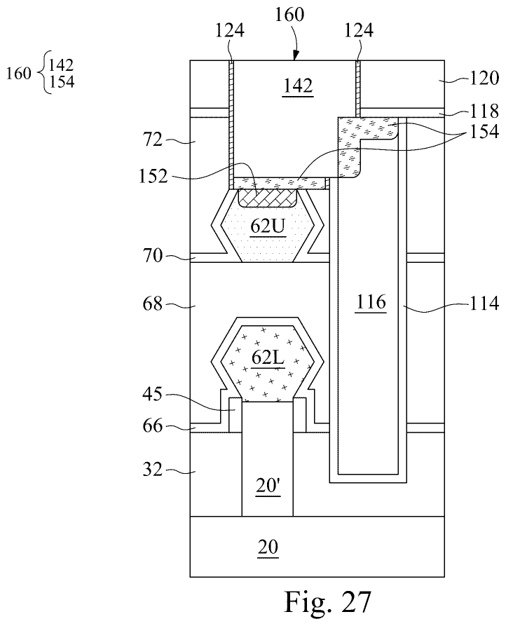

FIGS. 24 through 27 illustrate intermediate stages in the formation of a contact plug 160 (see FIG. 27) of a stacking transistor structure, in accordance with some embodiments. The contact plug 160 is similar to the contact plugs 140 described previously, except that the contact plug 160 includes both a metal fill 142 and a metal capping layer 154. Some of the materials and techniques used in FIGS. 24-27 are similar to those described previously for FIGS. 1A-23, and accordingly some details may not be repeated. FIG. 24 illustrates a structure similar to that shown previously in FIG. 4, which may be formed using materials and techniques similar to those described for FIGS. 1A-4. For example, FIG. 24 illustrates the structure after oxidation has occurred on the upper source/drain region 62U and on the contact plug 116, forming a silicon oxide layer 126 and a metal oxide layer 128, respectively.

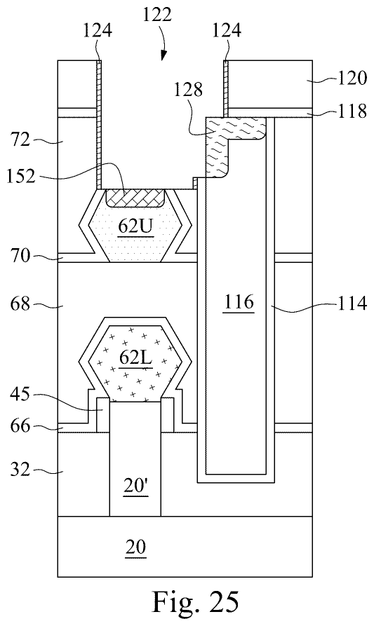

In FIG. 25, a selective silicide region 152 is formed on the upper source/drain region 62U, in accordance with some embodiments. Prior to formation of the selective silicide region 152, a first pre-clean process is performed to remove the silicon oxide layer 126. The first pre-clean process may be similar to the first pre-clean process described previously for FIG. 5. After performing the first pre-clean process, the silicon oxide layer 126 is removed, and the underlying upper source/drain region 62U is exposed.

After removing the silicon oxide layer 126, the selective silicide region 152 is formed on the upper source/drain region 62U. The selective silicide region 152 is deposited using materials and techniques that selectively form silicide materials on the material of the upper source/drain region 62U rather than on other materials such as dielectric layers, metals, or metal oxides. For example, the selective silicide region 152 may be formed by exposing the upper source/drain region 62U to appropriate precursors. In some embodiments, the selective silicide region 152 may be formed using suitable techniques, such as CVD, ALD, PVD, or the like. The selective silicide region 152 may comprise a titanium silicide or the like, though other silicides are possible.

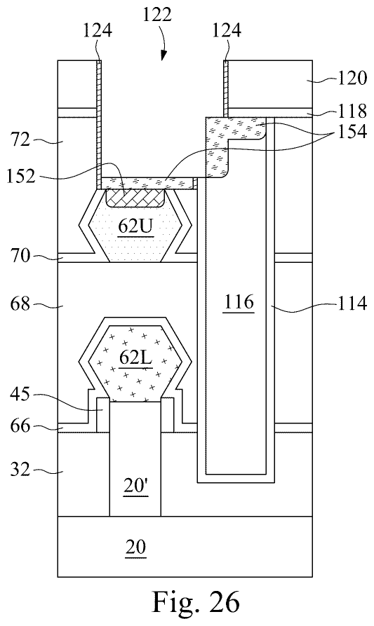

In FIG. 26, a metal capping layer 154 is formed on the selective silicide region 152 and on the contact plug 116, in accordance with some embodiments. The metal capping layer 154 makes physical and electrical contact to the selective silicide region 152 and to the contact plug 116. The metal capping layer 154 protects the selective silicide region 152 and the contact plug 116 during subsequent processing steps and also allows for a low-resistance electrical connection between the contact plug 160 and the contact plug 116. The metal capping layer 154 may form as multiple metal regions, as shown in FIG. 26, or may form as one continuous metal region.

The metal capping layer 154 may be a suitable metal deposited using a suitable technique. For example, in some embodiments, the metal capping layer 154 comprises a metal such as tungsten, molybdenum, ruthenium, iridium, cobalt, tantalum, rhenium, palladium, platinum, the like, or a combination thereof. In some embodiments, the metal capping layer 154 and the contact plug 116 may be the same metal, but the metal capping layer 154 and the contact plug 116 may be different metals in other embodiments. In some embodiments, the metal capping layer 154 may be formed using a deposition technique that deposits on metal-containing surfaces, such as surfaces of the selective silicide region 152 and the contact plug 116. In this manner, the metal capping layer 154 may be deposited using a “bottom-up” deposition technique. In some embodiments, the metal capping layer 154 may be deposited using CVD, PVD, ALD, or the like. In some embodiments, the precursors used to deposit the metal capping layer 154 also remove the metal oxide layer 128. Example precursors that also remove the metal oxide layer 128 include WCl₅, MoCl₅, or the like. Accordingly, the metal oxide layer 128 may be removed without performing a separate pre-clean process, allowing the metal capping layer 154 to deposit directly on the contact plug 116. Other precursors or deposition techniques are possible. In some embodiments, the selective silicide region 152 and the metal capping layer 154 may be deposited in the same process chamber (e.g., in situ).

In FIG. 27, a metal fill 142 is deposited into the opening 122 to form a contact plug 160, in accordance with some embodiments. The metal fill 142 and the metal capping layer 154 collectively form a contact plug 160. The metal fill 142 may be similar to the metal fill previously described for FIG. 9. For example, the metal fill 142 may comprise a metal similar to or different from the metal capping layer 154 and/or the contact plug 116. The contact plug 160 is electrically connected to the upper source/drain region 62U and is physically and electrically connected to the contact plug 116. Forming a selective silicide region 152 and a metal capping layer 154 as described herein can allow the interface between the contact plug 160 and the contact plug 116 to be free of silicide residue, which can reduce resistance and improve device performance.

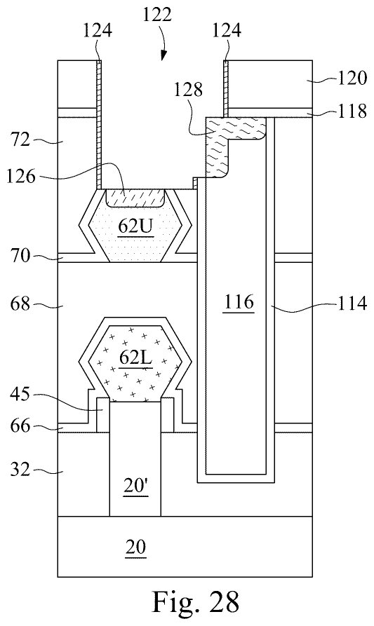

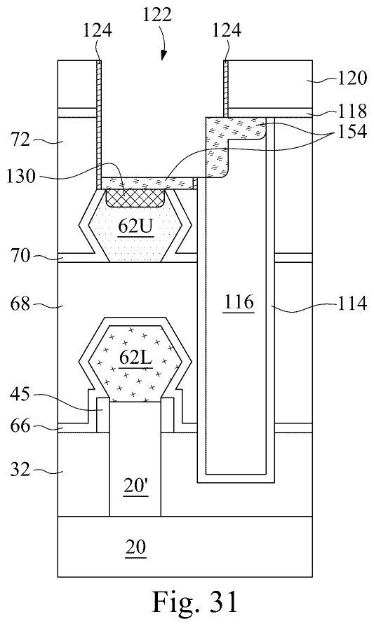

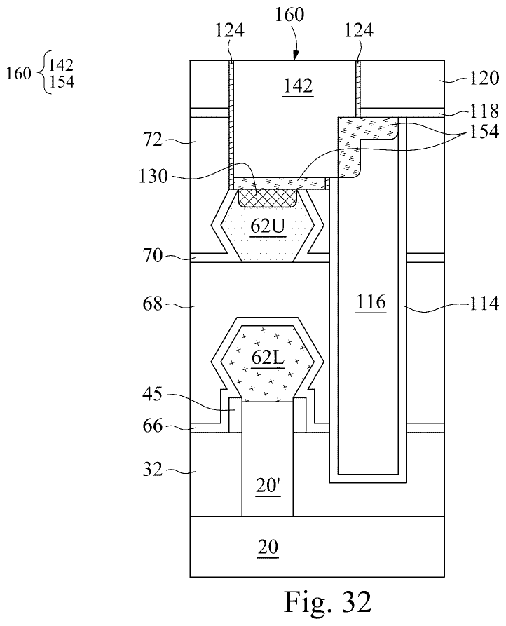

FIGS. 28 through 32 illustrate intermediate stages in the formation of a contact plug 160 (see FIG. 32) of a stacking transistor structure, in accordance with some embodiments. The contact plug 160 is formed using similar process steps as those described for FIGS. 24-27, except that the silicide is not formed using a selective deposition process. Some of the materials and techniques used in FIGS. 28-32 are similar to those described previously for FIGS. 1A-27, and accordingly some details may not be repeated. FIG. 28 illustrates a structure similar to that shown previously in FIG. 4, which may be formed using materials and techniques similar to those described for FIGS. 1A-4. For example, FIG. 28 illustrates the structure after oxidation has occurred on the upper source/drain region 62U and on the contact plug 116, forming a silicon oxide layer 126 and a metal oxide layer 128, respectively.

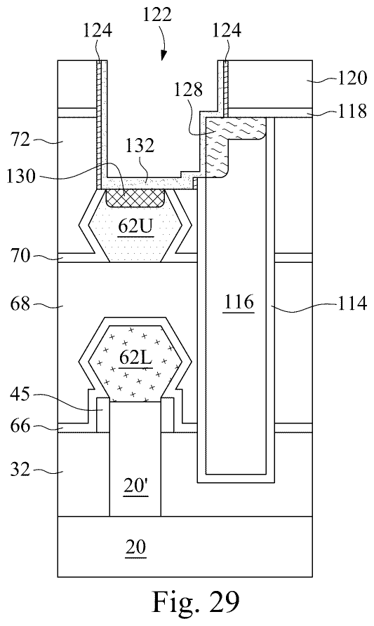

In FIG. 29, a silicide region 130 is formed on the upper source/drain region 62U, in accordance with some embodiments. Prior to formation of the silicide region 130, a first pre-clean process is performed to remove the silicon oxide layer 126. The first pre-clean process may be similar to the first pre-clean process described previously for FIG. 5. After performing the first pre-clean process, the silicon oxide layer 126 is removed, and the underlying upper source/drain region 62U is exposed. The silicide region 130 may be formed using materials or techniques similar to those described previously for FIG. 6. For example, in some embodiments, the silicide region 130 may be formed by exposing the structure to a metal-containing precursor that reacts with surfaces of the upper source/drain region 62 to form the silicide region 130. A nitridation process may be performed, in some cases. For example, for embodiments in which the silicide region 130 is a titanium silicide (e.g., TiSiₓ), the nitride layer may comprise titanium nitride (e.g., TiN) and/or titanium silicide nitride (e.g., TiSiN). Other materials are possible. In some cases, a residue layer 132 may be formed within the opening 122, which may be similar to the reside layer 132 described previously for FIG. 6.

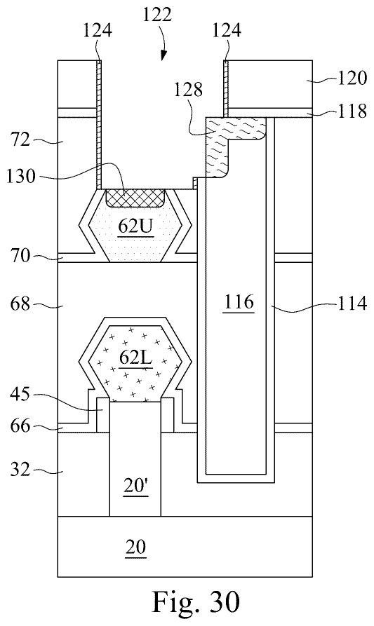

In FIG. 30, an etching process is performed to remove the residue layer 132, in accordance with some embodiments. In some cases, the etching process may be considered a “pull-back etch” or the like. The etching process may expose the silicide region 130 and/or the metal oxide layer 128. In some cases, the etching process may not fully remove the residue layer 132. The etching process may include a wet etching process and/or a dry etching process.

In FIG. 26, a metal capping layer 154 is formed on the selective silicide region 152 and on the contact plug 116, in accordance with some embodiments. The metal capping layer 154 may be similar to that described previously for FIG. 26, and may be formed using similar techniques. For example, in some embodiments, the precursors used to deposit the metal capping layer 154 also remove the metal oxide layer 128. The metal capping layer 154 makes physical and electrical contact to the selective silicide region 152 and to the contact plug 116. The metal capping layer 154 protects the selective silicide region 152 and the contact plug 116 during subsequent processing steps and also allows for a low-resistance electrical connection between the contact plug 160 and the contact plug 116. The metal capping layer 154 may form as multiple metal regions, as shown in FIG. 26, or may form as one continuous metal region. In some embodiments, the etching of the residue layer 132 and the deposition of the metal capping layer 154 may be performed in the same process chamber (e.g., in situ).

In FIG. 32, a metal fill 142 is deposited into the opening 122 to form a contact plug 160, in accordance with some embodiments. The metal fill 142 and the metal capping layer 154 collectively form a contact plug 160. The metal fill 142 may be similar to the metal fill previously described for FIG. 9 and/or the metal fill 142 described previously for FIG. 27. For example, the metal fill 142 may comprise a metal similar to or different from the metal capping layer 154 and/or the contact plug 116. The contact plug 160 is electrically connected to the upper source/drain region 62U and is physically and electrically connected to the contact plug 116. In some embodiments, excess metal fill 142 may be removed using a planarization process.

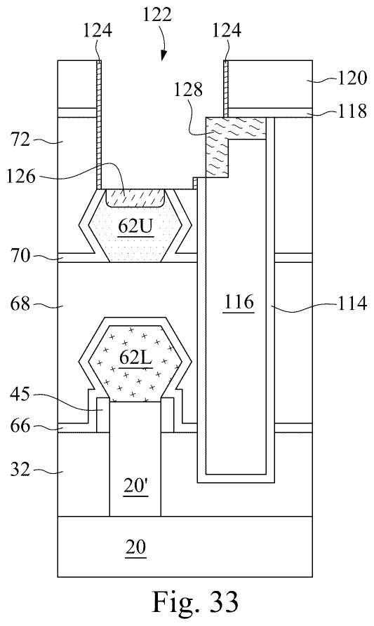

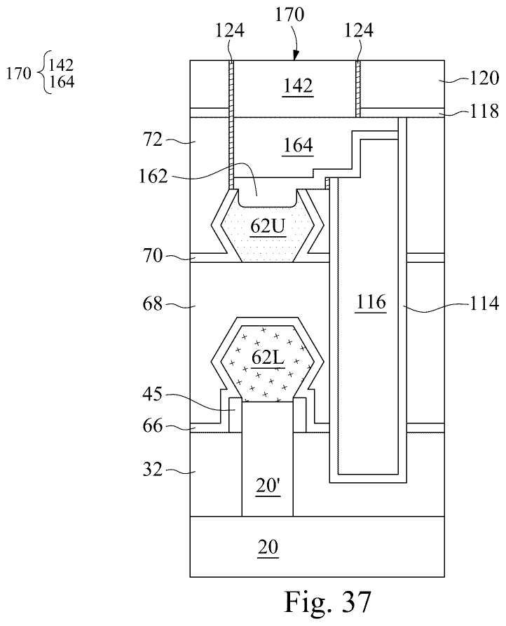

FIGS. 33 through 37 illustrate intermediate stages in the formation of a contact plug 170 (see FIG. 37) of a stacking transistor structure, in accordance with some embodiments. The contact plug 170 is formed using similar process steps as those described for the contact plug 160 of FIGS. 24-27, except that forming the silicide also removes the metal oxide layer 128. For example, the contact plug 170 comprises a metal capping layer 164 and a metal fill 142. Some of the materials and techniques used in FIGS. 33-37 are similar to those described previously for FIGS. 1A-32, and accordingly some details may not be repeated. FIG. 33 illustrates a structure similar to that shown previously in FIG. 4, which may be formed using materials and techniques similar to those described for FIGS. 1A-4. For example, FIG. 33 illustrates the structure after oxidation has occurred on the upper source/drain region 62U and on the contact plug 116, forming a silicon oxide layer 126 and a metal oxide layer 128, respectively.

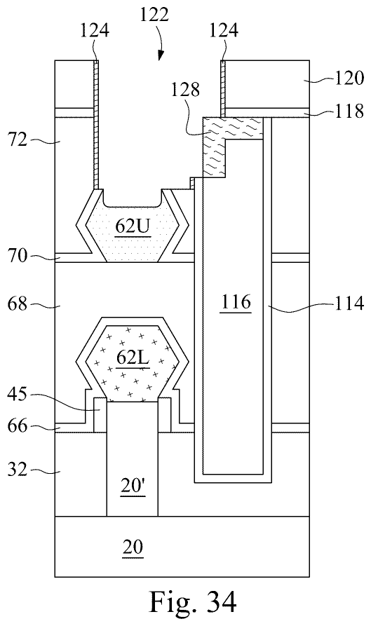

In FIG. 34, a pre-clean process is performed to remove the silicon oxide layer 126, in accordance with some embodiments. The pre-clean process may be similar to the first pre-clean described previously for FIG. 5. After performing the pre-clean process, the silicon oxide layer 126 is removed, and the underlying upper source/drain region 62U is exposed. In some embodiments, the pre-clean process does not remove the metal oxide layer 128.

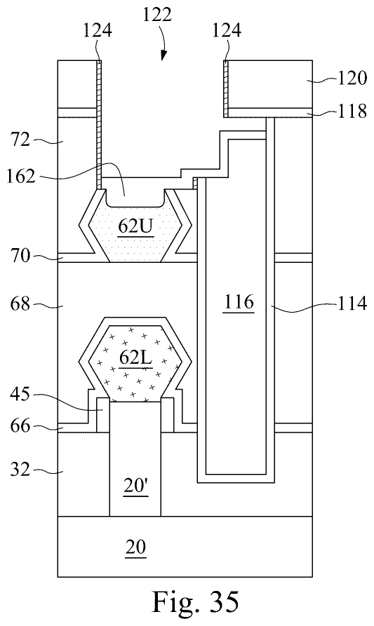

In FIG. 35, a silicide region 162 is formed on the upper source/drain region 62U, in accordance with some embodiments. The silicide region 162 may be formed by exposing the structure to a silicide precursor, such as a metal-containing precursor. In some embodiments, the silicide precursor also removes the metal oxide layer 128. Other silicide precursors are possible. Accordingly, the metal oxide layer 128 may be removed without performing a separate pre-clean process. In some embodiments, the silicide precursor also deposits on other surfaces, such as surfaces of the contact plug 116. The metal of the silicide region 162 may comprise titanium, vanadium, zinc, niobium, aluminum, zirconium, ruthenium, molybdenum, or other suitable metals. In some cases, the silicide region 162 may extend on more surfaces or different surfaces than shown in FIG. 37.

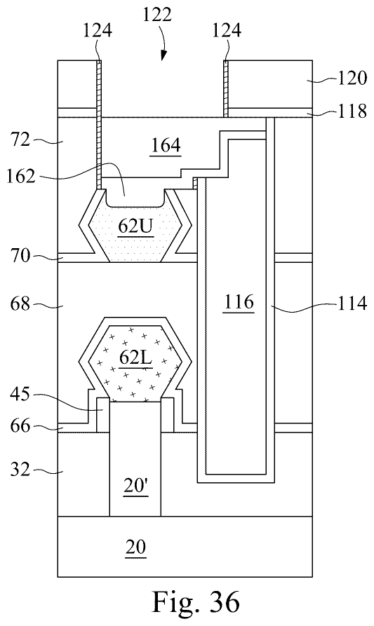

In FIG. 36, a metal capping layer 164 is formed in the opening 122, in accordance with some embodiments. The metal capping layer 164 may cover the silicide region 162, and may partially fill the opening 122. The metal capping layer 164 may be a suitable metal deposited using a suitable technique. For example, in some embodiments, the metal capping layer 164 comprises a metal such as tungsten, molybdenum, ruthenium, iridium, cobalt, tantalum, rhenium, palladium, platinum, zirconium, the like, or a combination thereof. In some embodiments, the metal capping layer 164 and the contact plug 116 may be the same metal, but the metal capping layer 164 and the contact plug 116 may be different metals in other embodiments. The metal capping layer 164 may be deposited using a “bottom-up” deposition technique, in some embodiments.

The metal capping layer 164 protects the silicide region 162 during subsequent processing steps and also allows for a low-resistance electrical connection between the contact plug 170 and the contact plug 116. In some embodiments, the deposition of the silicide region 162 and the deposition of the metal capping layer 154 may be performed in the same process chamber (e.g., in situ). Accordingly, a nitride layer may not be formed on the silicide region 162, because the silicide region 162 is protected by the metal capping layer 164 instead. In this manner, omitting the relatively higher resistance nitride layer can improve electrical connection between the contact plug 170 and the contact plug 116 and improve device performance.

In FIG. 37, a metal fill 142 is deposited into the opening 122 to form a contact plug 170, in accordance with some embodiments. The metal fill 142 and the metal capping layer 164 collectively form a contact plug 170. The metal fill 142 may be similar to the metal fill previously described for FIG. 9 and/or the metal fill 142 described previously for FIG. 27. For example, the metal fill 142 may comprise a metal similar to or different from the metal capping layer 164 and/or the contact plug 116. The contact plug 170 is electrically connected to the upper source/drain region 62U and is physically and electrically connected to the contact plug 116. In some embodiments, excess metal fill 142 may be removed using a planarization process. In this manner, the electrical connection between a source/drain contact plug and a VLI may be improved by omitting a nitride layer over the silicide region 162 and by removing the metal oxide layer 128.

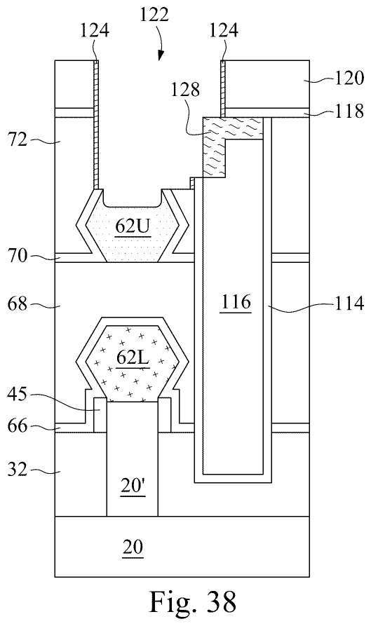

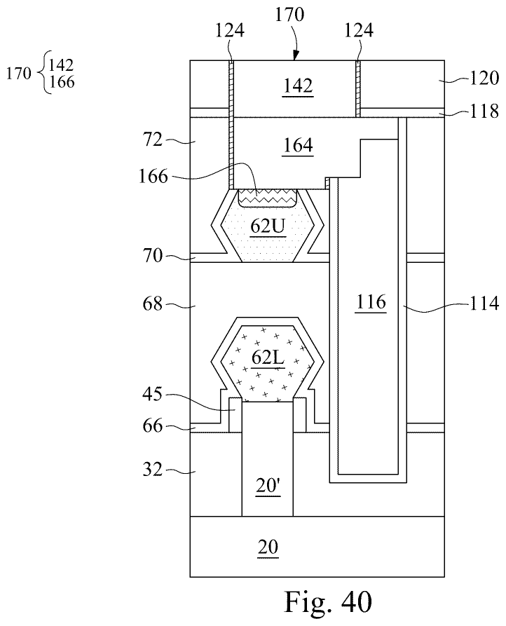

FIGS. 38 through 40 illustrate intermediate stages in the formation of a contact plug 170 (see FIG. 40) of a stacking transistor structure, in accordance with some embodiments. The contact plug 170 is formed using similar process steps as those described for the contact plug 170 of FIGS. 33-37, except that the silicide is selectively formed on the upper source/drain region 62U. For example, the contact plug 170 comprises a metal capping layer 164 and a metal fill 142, and forming the silicide also removes the metal oxide layer 128. Some of the materials and techniques used in FIGS. 38-40 are similar to those described previously for FIGS. 1A-37, and accordingly some details may not be repeated. FIG. 38 illustrates a structure similar to that shown previously in FIG. 34. For example, FIG. 38 illustrates the structure after the silicon oxide layer 126 has been removed by a pre-clean process.

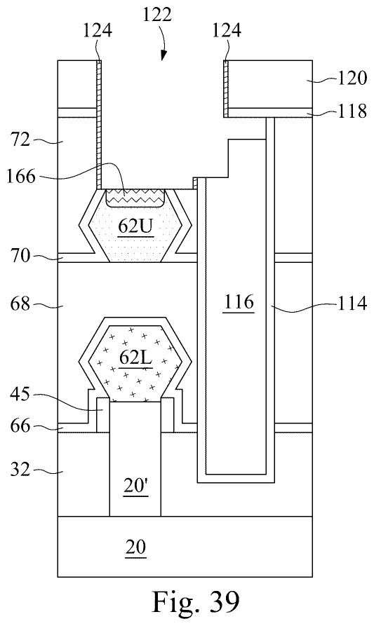

In FIG. 39, a selective silicide region 166 is formed on the upper source/drain region 62U, in accordance with some embodiments. The selective silicide region 166 is deposited using materials and techniques that selectively form on the material of the upper source/drain region 62U and also remove the metal oxide layer 128. For example, the selective silicide region 166 may be formed by exposing the upper source/drain region 62U to appropriate precursors that remove the metal oxide layer 128, such as Mo(CO)₆, MoO₂(thd)₂, MoCl₅, MoO₂Cl₂, [C₂H₅Ru(CO)₂]₂, Ru(CO)H₂[P(C₆H₅)₃]₃, Ru(TMM)(CO)₃, Ru₃(CO)₁₂, TDMAZ, ZrCl₄, TEMAZr, Zr(OEt)₄, or the like. Other precursors are possible. Accordingly, the metal oxide layer 128 may be removed without performing a separate pre-clean process. In some embodiments, the selective silicide region 166 may be formed using suitable techniques, such as CVD, ALD, PVD, or the like. The selective silicide region 166 may comprise, for example, molybdenum silicide, zirconium silicide, ruthenium silicide, or the like, though other silicides are possible. In some cases, the selective silicide region 166 may be formed using materials or techniques similar to the selective silicide region 152 described previously for FIG. 25. Depositing a selective silicide on the upper source/drain region 62U can avoid deposition of a silicide material or residue on the contact plug 116, which can reduce resistance.

In FIG. 40, a metal capping layer 164 and a metal fill 142 are deposited into the opening 122 to form a contact plug 170, in accordance with some embodiments. The metal fill 142 and the metal capping layer 164 collectively form a contact plug 170. The metal capping layer 164 may be deposited on the selective silicide region 166 and on the contact plug 116. The metal capping layer 164 may be a suitable metal deposited using a suitable technique, and may be similar to the metal capping layer 164 described previously for FIG. 36. For example, in some embodiments, the metal capping layer 164 comprises a metal such as tungsten, molybdenum, ruthenium, iridium, cobalt, tantalum, rhenium, palladium, platinum, zirconium, the like, or a combination thereof. In some embodiments, the metal capping layer 164 and the contact plug 116 may be the same metal, but the metal capping layer 164 and the contact plug 116 may be different metals in other embodiments. The metal capping layer 164 may be deposited using a “bottom-up” deposition technique, in some embodiments.

The metal fill 142 may be similar to the metal fill previously described for FIG. 9 and/or the metal fill 142 described previously for FIG. 27. For example, the metal fill 142 may comprise a metal similar to or different from the metal capping layer 164 and/or the contact plug 116. The contact plug 170 is electrically connected to the upper source/drain region 62U and is physically and electrically connected to the contact plug 116. In some embodiments, excess metal fill 142 may be removed using a planarization process. In this manner, the electrical connection between a source/drain contact plug and a VLI may be improved.

The embodiments of the present disclosure have some advantageous features. By removing the resistive metal oxide formed on a contact plug, resistance at the interface between the contact plug and another contact plug may be reduced. The techniques described herein also allow for an interface between two contact plugs to be formed with little or no resistive silicide residue. In some embodiments, the silicide residue is removed from a contact plug. In other embodiments, the silicide residue is blocked from being formed on the contact plug. In some embodiments, a metal capping layer is utilized to enhance the electrical connection between two contacts plugs. The techniques described herein allow for reduced resistance between two contact plugs, which can improve electrical connection and improve device performance.

In accordance with some embodiments of the present disclosure, a method includes forming a source/drain region; forming a contact etch stop layer over the source/drain region; forming an inter-layer dielectric over the contact etch stop layer; forming a first contact plug in the inter-layer dielectric and the contact etch stop layer; performing a first etching process to form an opening in the inter-layer dielectric and the contact etch stop layer, wherein the opening exposes surfaces of the source/drain region and surfaces of the first contact plug, wherein a metal oxide layer on the first contact plug is exposed by the opening; performing a silicide formation process to form a silicide region on a surface of the source/drain region; performing a second etching process to remove the metal oxide layer; and forming a second contact plug in the opening, wherein the second contact plug is electrically connected to the silicide region and the first contact plug, wherein an electrical conductivity of the silicide region is between an electrical conductivity of the source/drain region and an electrical conductivity of the second contact plug. In an embodiment, the silicide formation process includes forming a nitride layer over the silicide region. In an embodiment, the method includes, after performing the silicide formation process, depositing a sacrificial metal layer over the silicide region and over the metal oxide layer; and recessing the sacrificial metal layer. In an embodiment, the second etching process also removes a metal oxide from the sacrificial metal layer. In an embodiment, the method includes, before performing the silicide formation process, depositing a self-assembled material (SAM) over the first contact plug. In an embodiment, the second etching process is performed before the silicide formation process. In an embodiment, the silicide formation process is a selective process that selectively deposits silicide materials on the source/drain region. In an embodiment, the silicide formation process includes the second etching process that removes the metal oxide layer.

In accordance with some embodiments of the present disclosure, a method includes forming a conductive feature next to a source/drain region; exposing a first surface of the conductive feature and a first surface of the source/drain region; forming a metal oxide layer on the conductive feature and a silicon oxide layer on the source/drain region; removing the silicon oxide layer, wherein removing the silicon oxide layer exposes a second surface of the source/drain region; forming a silicide region on the second surface of the source/drain region; removing the metal oxide layer, wherein removing the metal oxide layer exposes a second surface of the conductive feature; and depositing a first conductive material on the silicide region and on the second surface of the conductive feature. In an embodiment, the conductive feature includes the first conductive material. In an embodiment, the method includes depositing a second conductive material on the first conductive material, wherein the conductive feature includes the second conductive material. In an embodiment, forming the silicide region also removes the metal oxide layer. In an embodiment, depositing the first conductive material also removes the metal oxide layer. In an embodiment, forming the silicide region also forms a residue layer over the metal oxide layer. In an embodiment, the metal oxide layer is a tungsten oxide.

In accordance with some embodiments of the present disclosure, a device includes a lower transistor that includes a lower source/drain region; an upper transistor that includes a upper source/drain region; a vertical interconnect extending next to the lower source/drain region and next to the upper source/drain region; a silicide region on the upper source/drain region; a first layer of a metal capping material on the silicide region; a second layer of the metal capping material on the vertical interconnect; and a layer of metal fill material covering the first layer of the metal capping material and the second layer of the metal capping material. In an embodiment, the metal fill material is different from the metal capping material. In an embodiment, the first layer of metal fill material is continuous with the second layer of metal fill material. In an embodiment, an interface between the second layer of the metal capping material and the vertical interconnect is free of metal oxide. In an embodiment, the silicide region extends between the second layer of the metal capping material and the vertical interconnect.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a source/drain region;
forming a contact etch stop layer over the source/drain region;
forming an inter-layer dielectric over the contact etch stop layer;
forming a first contact plug in the inter-layer dielectric and the contact etch stop layer;
performing a first etching process to form an opening in the inter-layer dielectric and the contact etch stop layer, wherein the opening exposes surfaces of the source/drain region and surfaces of the first contact plug, wherein a metal oxide layer on the first contact plug is exposed by the opening;
performing a silicide formation process to form a silicide region on a surface of the source/drain region;
performing a second etching process to remove the metal oxide layer; and
forming a second contact plug in the opening, wherein the second contact plug is electrically connected to the silicide region and the first contact plug, wherein an electrical conductivity of the silicide region is between an electrical conductivity of the source/drain region and an electrical conductivity of the second contact plug.

2. The method of claim 1, wherein the silicide formation process comprises forming a nitride layer over the silicide region.

3. The method of claim 1 further comprising:
after performing the silicide formation process, depositing a sacrificial metal layer over the silicide region and over the metal oxide layer; and
recessing the sacrificial metal layer.

4. The method of claim 3, wherein the second etching process also removes a metal oxide from the sacrificial metal layer.

5. The method of claim 1 further comprising, before performing the silicide formation process, depositing a self-assembled material (SAM) over the first contact plug.

6. The method of claim 1, wherein the second etching process is performed before the silicide formation process.

7. The method of claim 1, wherein the silicide formation process is a selective process that selectively deposits silicide materials on the source/drain region.

8. The method of claim 1, wherein the silicide formation process comprises the second etching process that removes the metal oxide layer.

9. A method comprising:
forming a conductive feature next to a source/drain region;
exposing a first surface of the conductive feature and a first surface of the source/drain region;
forming a metal oxide layer on the conductive feature and a silicon oxide layer on the source/drain region;
removing the silicon oxide layer, wherein removing the silicon oxide layer exposes a second surface of the source/drain region;
forming a silicide region on the second surface of the source/drain region;
removing the metal oxide layer, wherein removing the metal oxide layer exposes a second surface of the conductive feature; and
depositing a first conductive material on the silicide region and on the second surface of the conductive feature.

10. The method of claim 9, wherein the conductive feature comprises the first conductive material.

11. The method of claim 9 further comprising depositing a second conductive material on the first conductive material, wherein the conductive feature comprises the second conductive material.

12. The method of claim 9, wherein forming the silicide region also removes the metal oxide layer.

13. The method of claim 9, wherein depositing the first conductive material also removes the metal oxide layer.

14. The method of claim 9, wherein forming the silicide region also forms a residue layer over the metal oxide layer.

15 The method of claim 9, wherein the metal oxide layer is a tungsten oxide.

16. A device comprising:
a lower transistor comprising a lower source/drain region;
an upper transistor comprising a upper source/drain region;
a vertical interconnect extending next to the lower source/drain region and next to the upper source/drain region;
a silicide region on the upper source/drain region;
a first layer of a metal capping material on the silicide region;
a second layer of the metal capping material on the vertical interconnect; and
a layer of metal fill material covering the first layer of the metal capping material and the second layer of the metal capping material.

17. The device of claim 16, wherein the metal fill material is different from the metal capping material.

18. The device of claim 16, wherein the first layer of metal fill material is continuous with the second layer of metal fill material.

19. The device of claim 16, wherein an interface between the second layer of the metal capping material and the vertical interconnect is free of metal oxide.

20. The device of claim 16, wherein the silicide region extends between the second layer of the metal capping material and the vertical interconnect.
